(19) United States
(12) Patent Application Publication
(10) Pub. No.: US 2026/0011649 A1
(43) Pub. Date: Jan. 8, 2026

(54) SEMICONDUCTOR PACKAGE

(71) Applicant: Samsung Electronics Co., Ltd., Suwon-si (KR)

(72) Inventors: Gyunghwan OH, Suwon-si (KR); Seunggeol Ryu, Suwon-si (KR)

(21) Appl. No.: 19/054,465

(22) Filed: Feb. 14, 2025

(30) Foreign Application Priority Data
Jul. 3, 2024 (KR) 10-2024-0087419

(51) Int. Cl. H01L 23/538; H01L 23/00; H01L 23/498; H01L 25/065; H01L 25/18; H10B 80/00; H10D 80/30

(52) U.S. Cl. CPC H01L 23/5385; H01L 23/49816; H01L 23/49866; H01L 23/5386; H01L 24/48; H01L 25/0657; H01L 25/18; H01L 24/32; H01L 24/49; H01L 2224/32145; H01L 2224/32225; H01L 2224/48235; H01L 2224/4903; H01L 2225/0651; H01L 2225/06562; H01L 2924/3511; H10B 80/00; H10D 80/30

(57) ABSTRACT

A semiconductor package may include a first substrate, semiconductor dies stacked on the first substrate in a direction perpendicular to a top surface of the first substrate to have a stepwise structure, a mold layer disposed on the first substrate to cover the semiconductor dies, a second substrate disposed on the mold layer, and vertical conductive lines electrically connecting the semiconductor dies to the second substrate. The first substrate may include a first region and a second region. The first region may have a first thermal expansion coefficient, and the second region may have a second thermal expansion coefficient. The first thermal expansion coefficient may be different from the second thermal expansion coefficient.

### CROSS-REFERENCE TO RELATED APPLICATIONS

This U.S. non-provisional patent application claims priority under 35 U.S.C. § 119 to Korean Patent Application No. 10-2024-0087419, filed on Jul. 3, 2024, in the Korean Intellectual Property Office, the entire contents of which are hereby incorporated by reference.

### BACKGROUND OF THE INVENTION

The present disclosure relates to a semiconductor package.

A semiconductor package includes a semiconductor chip that is provided to be easily used as a part of an electronic product. In general, the semiconductor package includes a printed circuit board (PCB) and a semiconductor chip, which is mounted on the PCB and is electrically connected to the PCB using bonding wires or bumps. With development of the electronics industry, many studies are being conducted to improve reliability of the semiconductor package and to reduce a size of the semiconductor package.

### SUMMARY

An embodiment of the inventive concept provides a semiconductor package with improved reliability.

According to an embodiment of the inventive concept, a semiconductor package may include a first substrate, semiconductor dies stacked on the first substrate in a direction perpendicular to a top surface of the first substrate to have a stepwise structure, a mold layer disposed on the first substrate to cover the semiconductor dies, a second substrate disposed on the mold layer, and vertical conductive lines electrically connecting the semiconductor dies to the second substrate. The first substrate may include a first region and a second region. The first region may have a first thermal expansion coefficient, and the second region may have a second thermal expansion coefficient. The first thermal expansion coefficient may be different from the second thermal expansion coefficient.

According to an embodiment of the inventive concept, a semiconductor package may include a first substrate, semiconductor dies stacked on the first substrate in a direction perpendicular to a top surface of the first substrate to have a stepwise structure, a mold layer disposed on the first substrate to cover the semiconductor dies, a second substrate disposed on the mold layer, and vertical conductive lines electrically connecting the semiconductor dies to the second substrate. The first substrate may include a first region and a second region. The first region may include first metal patterns and a first insulating pattern covering the first metal patterns, and the second region may include second metal patterns and a second insulating pattern covering the second metal patterns. A width of each of the first metal patterns in a first direction may be larger than a width of each of the second metal patterns in the first direction, and the first direction may be parallel to the top surface of the first substrate.

According to an embodiment of the inventive concept, a semiconductor package may include a first substrate, semiconductor dies stacked on the first substrate in a direction perpendicular to a top surface of the first substrate to have a stepwise structure, a mold layer disposed on the first substrate to cover the semiconductor dies, a second substrate disposed on the mold layer, the second substrate including upper redistribution patterns and upper redistribution insulating layers enclosing the upper redistribution patterns, and vertical conductive lines electrically connecting the semiconductor dies to the upper redistribution patterns of the second substrate. The first substrate may include a first region and a second region. The first region may include first metal patterns and a first insulating pattern covering the first metal patterns, and the second region may include second metal patterns and a second insulating pattern covering the second metal patterns. The number of the first metal patterns may be greater than the number of the second metal patterns.

### BRIEF DESCRIPTION OF THE DRAWINGS

FIG. 1 is a sectional view illustrating a semiconductor package according to an embodiment of the inventive concept.

FIGS. 2 to 7 are sectional views illustrating a method of fabricating a semiconductor package, according to an embodiment of the inventive concept.

FIG. 8 is a sectional view illustrating a semiconductor package according to an embodiment of the inventive concept.

### DETAILED DESCRIPTION

Example embodiments of the inventive concepts will now be described more fully with reference to the accompanying drawings, in which example embodiments are shown.

Throughout the disclosure, spatially relative terms, such as “beneath,” “below,” “lower,” “above,” “upper,” “horizontal,” “vertical” and the like, may be used herein for ease of description to describe positional relationships, such as illustrated in the figures. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

As used herein, components described as being “electrically connected” or “electrically coupled” are configured such that an electrical signal can be transferred from one component to the other (although such electrical signal may be attenuated in strength as it transferred and may be selectively transferred).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

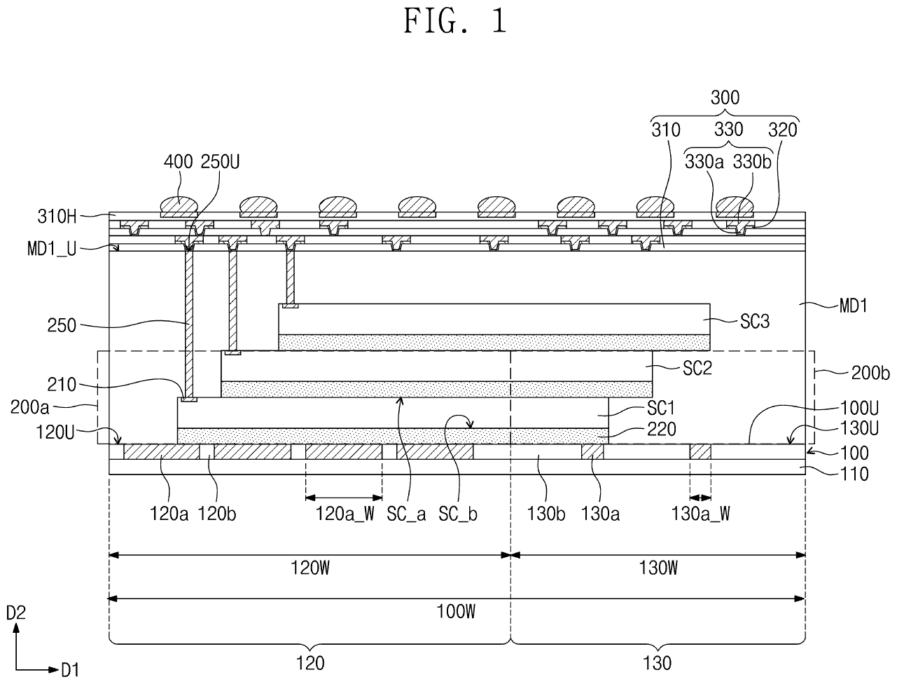

FIG. 1 is a sectional view illustrating a semiconductor package according to an embodiment of the inventive concept.

Referring to FIG. 1, a lower insulating layer 110 may be disposed. The lower insulating layer 110 may include a photosensitive polymer. For example, the lower insulating layer 110 may include at least one of photosensitive polyimide (PSPI), polybenzoxazole (PBO), phenol-based polymers, or benzocyclobutene-based polymers (BCB).

A first substrate 100 may be disposed on the lower insulating layer 110. The first substrate 100 may include a first region 120 and a second region 130. A width 100W of the first substrate 100 in a first direction D1 may range from 6.2 mm to 8.2 mm. The first direction D1 may be parallel to a top surface 100U of the first substrate 100.

A width 120W of the first region 120 in the first direction D1 may be equal to or different from a width 130W of the second region 130 in the first direction D1. The width 120W of the first region 120 in the first direction D1 may be larger than the width 130W of the second region 130 in the first direction D1. In an embodiment, a ratio of the width 120W of the first region 120 in the first direction D1 to the width 130W of the second region 130 in the first direction D1 may range from 1:1 to 7:3. The width 120W of the first region 120 in the first direction D1 may range from 3.2 mm to 5.74 mm. The width 130W of the second region 130 in the first direction D1 may range from 1.86 mm to 4.1 mm.

The first region 120 may have a first thermal expansion coefficient, and the second region 130 may have a second thermal expansion coefficient. The first thermal expansion coefficient may be different from the second thermal expansion coefficient, and in an embodiment, the first thermal expansion coefficient may be greater than the second thermal expansion coefficient.

The first region 120 may include first metal patterns 120a and first insulating patterns 120b covering the first metal patterns 120a. For example, the first insulating patterns 120b may cover side surfaces of the first metal patterns 120a as shown in FIG. 1. In certain embodiments, the first insulating patterns 120b may cover top surfaces and side surfaces of the first metal patterns 120a. For example, the first insulating patterns 120b may cover at least a portion of the top surfaces of the first metal patterns 120a in certain embodiments. The second region 130 may include second metal patterns 130a and second insulating patterns 130b covering the second metal patterns 130a. For example, the second insulating patterns 130b may cover side surfaces of the second metal patterns 130a as shown in FIG. 1. In certain embodiments, the second insulating patterns 130b may cover top surfaces and side surfaces of the second metal patterns 130a. For example, the second insulating patterns 130b may cover at least a portion of the top surfaces of the second metal patterns 130a in certain embodiments. The number of the first metal patterns 120a may be different from the number of the second metal patterns 130a, e.g., in a cross-sectional view as shown in FIG. 1. For example, densities of the first and second metal patterns 120a and 130a in the respective first and second regions 120 and 130 may be different from each other. For example, a ratio of an area of the first metal patterns 120a to the first region 120 in a plan view may be different from a ratio of an area of the second metal patterns 130a to the second region 130 in the plan view. The number of the first metal patterns 120a may be greater than the number of the second metal patterns 130a, e.g., in a cross-sectional view as shown in FIG. 1. For example, the density of the first metal pattern 120a in the first region 120 may be greater than the density of the second metal patterns 130a in the second region 130. For example, the ratio of the area of the first metal patterns 120a to the first region 120 may be greater than the ratio of the area of the second metal patterns 130a to the second region 130. In an embodiment, a ratio of the number of the first metal patterns 120a to the number of the second metal patterns 130a may range from 1:0.1 to 1:0.7. In certain embodiments, the ratio of the area of the first metal patterns 120a to the first region 120 may be 1.5 times to 10 times the ratio of the area of the second metal patterns 130a to the second region 130.

A width 120a_W of each of the first metal patterns 120a in the first direction D1 may be different from a width 130a_W of each of the second metal patterns 130a in the first direction D1. The width 120a_W of each of the first metal patterns 120a in the first direction D1 may be larger than the width 130a_W of each of the second metal patterns 130a in the first direction D1. In an embodiment, a ratio of a width of each of the first metal patterns 120a in the first direction D1 to a width of each of the second metal patterns 130a in the first direction D1 may range from 1:0.1 to 1:0.7.

The first metal patterns 120a and the second metal patterns 130a may include the same material (e.g., copper). The first insulating patterns 120b and the second insulating patterns 130b may include the same material (e.g., a photosensitive polymer). The first insulating patterns 120b and the second insulating patterns 130b may include at least one of photosensitive polyimide (PSPI), polybenzoxazole (PBO), phenol-based polymers, or benzocyclobutene-based polymers (BCB).

Semiconductor dies SC1, SC2, and SC3 may be stacked on the top surface 100U of the first substrate 100 in a second direction D2 perpendicular to the top surface 100U of the first substrate 100 (e.g., in an offset stacking manner). The semiconductor dies SC1, SC2, and SC3 may have a stepwise structure. For example, the semiconductor dies SC1, SC2, and SC3 having the stepwise structure may be stacked in a vertical direction (the second direction D2) and may be sequentially shifted in a horizontal direction (the first direction D1) as shown in FIG. 1.

The semiconductor dies SC1, SC2, and SC3 may be semiconductor dies, on which memory devices are integrated. The semiconductor dies SC1, SC2, and SC3 may include a first semiconductor die SC1, a second semiconductor die SC2, and a third semiconductor die SC3. The first semiconductor die SC1 may be one of the semiconductor dies SC1, SC2, and SC3 that is closest to the first substrate 100. The third semiconductor die SC3 may be a die that is disposed on the first semiconductor die SC1. The second semiconductor die SC2 may be interposed between the first semiconductor die SC1 and the third semiconductor die SC3.

The first semiconductor die SC1 may be disposed on the top surface 100U of the first substrate 100. The second semiconductor die SC2 may be stacked on the first semiconductor die SC1 and may be shifted toward the second region 130 (e.g., shifted in the first direction D1 from the positon where the first semiconductor die SC1 is placed as shown in FIG. 1). The third semiconductor die SC3 may be stacked on the second semiconductor die SC2 and may be shifted toward the second region 130 (e.g., shifted in the first direction D1 from the positon where the second semiconductor die SC2 is placed as shown in FIG. 1).

FIG. 1 illustrates an example, in which three semiconductor dies are provided, but the number of the semiconductor dies in the semiconductor package may not be limited to three and may be greater or less than three.

Each of the semiconductor dies SC1, SC2, and SC3 may include a top surface SC_a and a bottom surface SC_b, which are opposite to each other. The bottom surface SC_b may be a surface of each of the semiconductor dies SC1, SC2, and SC3 facing the first substrate 100. The top surface SC_a of each of the semiconductor dies SC1, SC2, and SC3 may be an active surface.

A contact pad 210 may be disposed on the top surface SC_a of each of the semiconductor dies SC1, SC2, and SC3. The contact pad 210 may include or may be a coupling terminal, which is electrically coupled/connected to a corresponding one of the semiconductor dies SC1, SC2, and SC3 in order to communicate information or provide power to the same.

A die adhesive layer 220 may be disposed below the bottom surface SC_b of each of the semiconductor dies SC1, SC2, and SC3. The die adhesive layer 220, which is disposed below the bottom surface SC_b of the first semiconductor die SC1, may attach the first semiconductor die SC1 to the first substrate 100. The die adhesive layer 220 disposed below the bottom surface SC_b of the second semiconductor die SC2 may be used to attach the first semiconductor die SC1 to the second semiconductor die SC2 and the die adhesive layer 220 disposed below the bottom surface SC_b of the third semiconductor die SC2 may be used to attach the second semiconductor die SC2 to the third semiconductor die SC3.

Vertical connecting portions 250 may be disposed on the contact pads 210. For example, each of the vertical connecting portions 250 may be connected (e.g., electrically connected) to a corresponding one of the contact pads 210 in the semiconductor dies SC1, SC2, and SC3. Vertical connecting portions 250 disclosed in the present application may be conductive lines/wires extending in a vertical direction, and may be called as vertical conductive lines in some other parts of the disclosure and in the claims. The vertical connecting portions 250 may extend in the second direction D2. In an embodiment, the vertical connecting portions 250 may be formed of or include at least one of copper, aluminum, tungsten, or titanium, but the inventive concept is not limited to these examples.

A first mold layer MD1 may be disposed on the first substrate 100. The first mold layer MD1 may cover the semiconductor dies SC1, SC2, and SC3 and the vertical connecting portions 250. A top surface MD1_U of the first mold layer MD1 may be located on the same plane as a top surface 250U of each of the vertical connecting portions 250. For example, the top surfaces of the vertical connecting portions 250 may be at the same level. The first mold layer MD1 may include, for example, an epoxy molding compound (EMC).

A portion of the first mold layer MD1 and portions of the semiconductor dies SC1, SC2, and SC3, which are placed on the first region 120 of the first substrate 100, may be referred to as a chip region 200a. Other portion of the first mold layer MD1 and other portions of the semiconductor dies SC1, SC2, and SC3, which are placed on the second region 130 of the first substrate 100, may be referred to as a molding region 200b. In the chip region 200a, a volume (or space) of the portions of the semiconductor dies SC1, SC2, and SC3 may be larger than that of the portion of the first mold layer MD1. In the molding region 200b, a volume (or space) of the other portion of the first mold layer MD1 may be larger than a volume (or space) of the other portions of the semiconductor dies SC1, SC2, and SC3. In this case, a thermal expansion coefficient (i.e., the rate of volume change caused by heat) may be smaller in the chip region 200a than in the molding region 200b. Due to the difference in the thermal expansion coefficients between the chip region 200a and the molding region 200b, a warpage failure may occur in the semiconductor package.

According to an embodiment of the inventive concept, the first and second regions 120 and 130 may be configured to reduce the variation in the thermal expansion coefficient of the semiconductor package. A content of a metallic material (e.g., copper) with a high thermal expansion coefficient may be higher in the first region 120 than in the second region 130. In this case, the first thermal expansion coefficient of the first region 120 may be higher than the second thermal expansion coefficient of the second region 130. Thus, the rate of volume change caused by heat may be larger in the first region 120 than in the second region 130. Thus, it may be possible to reduce the difference in the thermal expansion coefficient between the chip region 200a and the molding region 200b. For example, the difference between the thermal expansion coefficient of the chip region 200a and the thermal expansion coefficient of the molding region 200b may be compensated or offset by the difference between the first thermal expansion coefficient of the first region 120 and the second thermal expansion coefficient of the second region 130. As a result, it may be possible to reduce a warpage failure in the semiconductor package.

As a result, it may be possible to prevent the semiconductor dies SC1, SC2, and SC3 of the semiconductor package from being damaged and to improve the reliability of the semiconductor package.

While the above embodiment describes that the chip region 200a and the molding region 200b include portions of the first to third semiconductor dies SC1, SC2, and SC3, the chip region 200a and the molding region 200b may include portions of the first and second semiconductor dies SC1 and SC2 (e.g., bottom two semiconductor dies) in certain embodiments as illustrated in FIG. 1.

For example, the first substrate 100 may be divided into two regions (the first region 120 and the second region 130) by a plane extending in a vertical direction and perpendicular to a line extending in the first direction D1. For example, one part of the first substrate 100 is the first region 120 and the other part of the first substrate 100 is the second region 130. The chip region 200a is a portion of a semiconductor package which is vertically overlapping the first region 120 of the first substrate 100 from a level of the top surface 100U of the first substrate 100 to a level of the top surface SC_a of the second semiconductor die SC2 (when the chip region 200a includes bottom two semiconductor dies disposed on the first substrate 100) or the third semiconductor die SC3 (when the chip region 200a includes bottom three semiconductor dies disposed on the first substrate 100). The molding region 200b is a portion of the semiconductor package with is vertically overlapping the second region 130 of the first substrate 100 from the level of the top surface 100U of the first substrate 100 to the level of the top surface SC_a of the second semiconductor die SC2 (when the molding region 200b includes bottom two semiconductor dies disposed on the first substrate 100) or to the level of the top surface SC_a of the third semiconductor die SC3 (when the molding region 200b includes bottom three semiconductor dies disposed on the first substrate 100).

In example embodiments, when bottom two semiconductor dies are included in the chip region 200a and the molding region 200b, three or more semiconductor dies may be stacked on the first substrate 100, and when three semiconductor dies are included in the chip region 200a and the molding region 200b, four or more semiconductor dies may be stacked on the first substrate 100.

A second substrate 300 may be disposed on the first mold layer MD1. In an embodiment, the second substrate may be a redistribution substrate. The second substrate 300 may include upper redistribution patterns 330 and upper redistribution insulating layers 310 covering the upper redistribution patterns 330. For example, the upper redistribution insulating layers 310 may cover/contact side surfaces and/or top surfaces of the upper redistribution patterns 330. The upper redistribution patterns 330 may include an upper redistribution line 330b and an upper redistribution contact 330a electrically connected to the upper redistribution line 330b.

The upper redistribution contact 330a may be provided to penetrate a corresponding one of the upper redistribution insulating layers 310, and the upper redistribution line 330b may be disposed on the corresponding upper redistribution insulating layer 310 and may be electrically connected to the upper redistribution contact 330a. An upper redistribution seed pattern 320 may be interposed between the upper redistribution contact 330a and the corresponding upper redistribution insulating layer 310 and may extend into a space between the upper redistribution line 330b and the corresponding upper redistribution insulating layer 310. In example embodiments, the upper redistribution line 330b and the upper redistribution contact 330a may contact each other. In certain embodiments, the upper redistribution line 330b and the upper redistribution contact 330a may be integrally formed as one body without a boundary between the upper redistribution line 330b and the upper redistribution contact 330a.

Each of the upper redistribution patterns 330 may be connected (e.g., electrically connected) to a corresponding one of the vertical connecting portions 250. Thus, the semiconductor dies SC1, SC2, and SC3 may be electrically connected to the second substrate 300. The upper redistribution pattern 330 may include at least one of metallic materials (e.g., copper, titanium, and/or alloys thereof). The upper redistribution seed pattern 320 may include at least one of metallic materials (e.g., copper, titanium, and/or alloys thereof).

First connection terminals 400 may be disposed on the second substrate 300. The first connection terminals 400 may be disposed on the uppermost one (e.g., an upper redistribution insulating layer 310H) of the upper redistribution insulating layers 310. The first connection terminals 400 may include or may be solder balls or solder bumps. Depending on the kind and arrangement of the first connection terminals 400, the semiconductor package may be classified into a ball grid array (BGA) type, a fine ball-grid array (FBGA) type, or a land grid array (LGA) type. The first connection terminal 400 may be formed of or include at least one of tin (Sn), silver (Ag), copper (Cu), nickel (Ni), bismuth (Bi), indium (In), antimony (Sb), cerium (Ce), or alloys thereof.

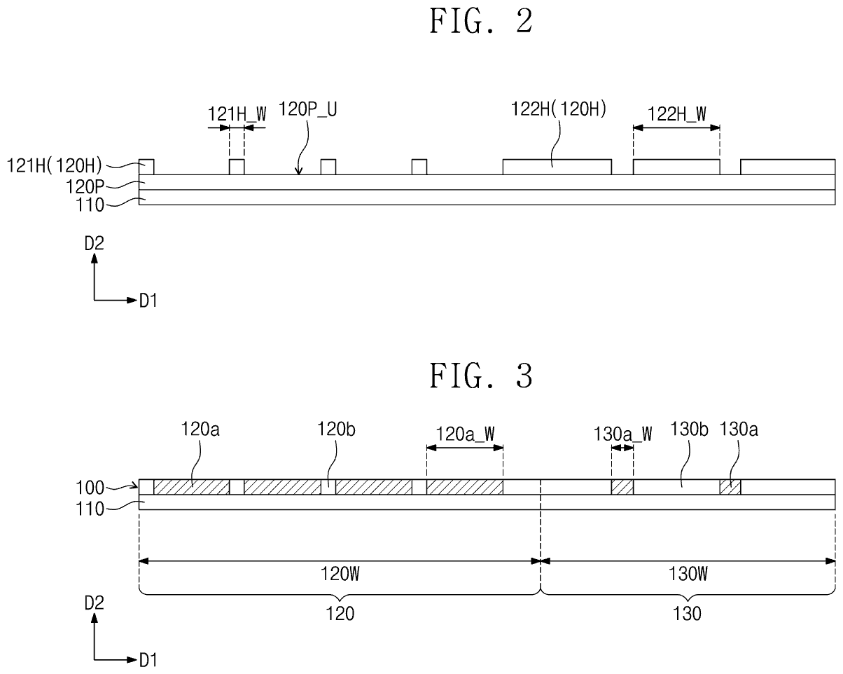

FIGS. 2 to 7 are sectional views illustrating a method of fabricating a semiconductor package, according to an embodiment of the inventive concept. For concise description, elements previously described with reference to FIG. 1 may be identified by the same reference numbers without repeating overlapping descriptions thereof.

Referring to FIG. 2, a preliminary insulating layer 120P may be formed on the lower insulating layer 110. A hard mask pattern 120H may be formed on the preliminary insulating layer 120P. The hard mask pattern 120H may include first hard mask patterns 121H and second hard mask patterns 122H. A width 121H_W of each of the first hard mask patterns 121H in the first direction D1 may be smaller than a width 122H_W of each of the second hard mask patterns 122H in the first direction D1. The hard mask pattern 120H may have an opening, which is formed between the first and second hard mask patterns 121H and 122H to expose a top surface 120P_U of the preliminary insulating layer 120P.

Referring to FIG. 3, the first substrate 100 including the first and second regions 120 and 130 may be formed. The first region 120 may include first metal patterns 120a and first insulating patterns 120b enclosing the first metal patterns 120a. In an embodiment, the formation of the first metal patterns 120a may include performing a patterning process using the first hard mask patterns 121H as an etch mask to form preliminary first metal holes/trenches penetrating the preliminary insulating layer 120P (e.g., in a vertical direction), filling the preliminary first metal holes/trenches with a metallic material, and planarizing the metallic material to expose a top surface of the preliminary insulating layer 120P. Portions of the preliminary insulating layer 120P covering the first metal patterns 120a may be referred to as the first insulating patterns 120b. For example, the first insulating patterns 120b may cover/contact side surfaces of the first metal patterns 120a.

The second region 130 may include the second metal patterns 130a and the second insulating patterns 130b enclosing the second metal patterns 130a. In an embodiment, the formation of the second metal patterns 130a may include performing a patterning process using the second hard mask patterns 122H as an etch mask to form preliminary second metal holes/trenches penetrating the preliminary insulating layer 120P (e.g., in a vertical direction), filling the preliminary second metal holes/trenches with a metallic material, and planarizing the metallic material to expose a top surface of the preliminary insulating layer 120P. Portions of the preliminary insulating layer 120P covering the second metal patterns 130a will be referred to as the second insulating patterns 130b. For example, the second insulating patterns 130b may cover/contact side surfaces of the second metal patterns 130a.

The number of the first metal patterns 120a may be different from the number of the second metal patterns 130a. The number of the first metal patterns 120a may be greater than the number of the second metal patterns 130a. In an embodiment, a ratio of the number of the first metal patterns 120a to the number of the second metal patterns 130a may range from 1:0.1 to 1:0.7.

The width of each of the first metal patterns 120a in the first direction D1 may be different from the width of each of the second metal patterns 130a in the first direction D1. For example, the width of each of the first metal patterns 120a in the first direction D1 may be larger than the width of each of the second metal patterns 130a in the first direction D1. In an embodiment, a ratio of the width of each of the first metal patterns 120a in the first direction D1 to the width of each of the second metal patterns 130a in the first direction D1 may range from 1:0.1 to 1:0.7.

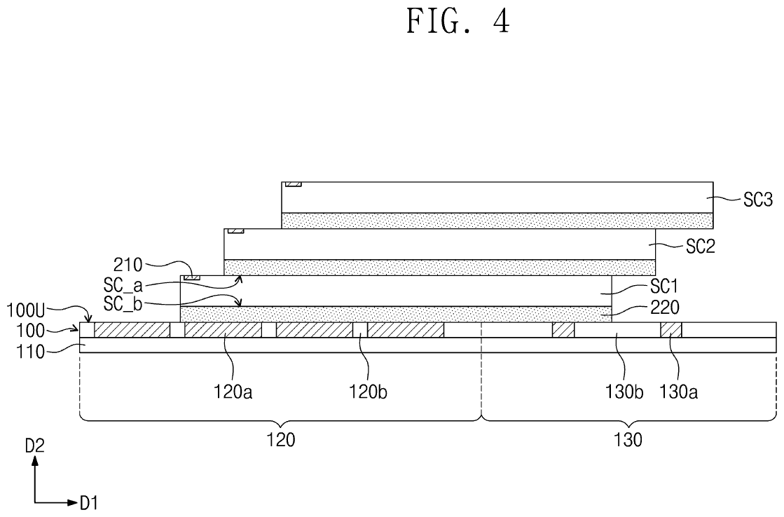

Referring to FIG. 4, the semiconductor dies SC1, SC2, and SC3 may be stacked on the first substrate 100 in the second direction D2. The semiconductor dies SC1, SC2, and SC3 may be stacked on the first substrate 100 to form a stepwise structure. The semiconductor dies SC1, SC2, and SC3 may include the first semiconductor die SC1, the second semiconductor die SC2, and the third semiconductor die SC3. The first semiconductor die SC1 may be one of the semiconductor dies SC1, SC2, and SC3 that is closest to the first substrate 100. The third semiconductor die SC3 may be a die that is disposed on the first semiconductor die SC1. The second semiconductor die SC2 may be interposed between the first semiconductor die SC1 and the third semiconductor die SC3.

The first semiconductor die SC1 may be stacked on the top surface 100U of the first substrate 100. The second semiconductor die SC2 may be stacked on the first semiconductor die SC1 and may be shifted toward the second region 130. The third semiconductor die SC3 may be stacked on the second semiconductor die SC2 and may be shifted toward the second region 130.

Each of the semiconductor dies SC1, SC2, and SC3 may include the top surface SC_a and the bottom surface SC_b, which are opposite to each other. The bottom surface SC_b may be a surface of each of the semiconductor dies SC1, SC2, and SC3 facing the first substrate 100. The contact pad 210 may be formed on the top surface SC_a of each of the semiconductor dies SC1, SC2, and SC3.

The die adhesive layer 220 may be formed below the bottom surface SC_b of each of the semiconductor dies SC1, SC2, and SC3. The die adhesive layer 220, which is formed below the bottom surface SC_b of the first semiconductor die SC1, may be used to attach the first semiconductor die SC1 to the first substrate 100. The die adhesive layers 220 may be used to attach the first semiconductor die SC1 to the second semiconductor die SC2 and to attach the second semiconductor die SC2 to the third semiconductor die SC3.

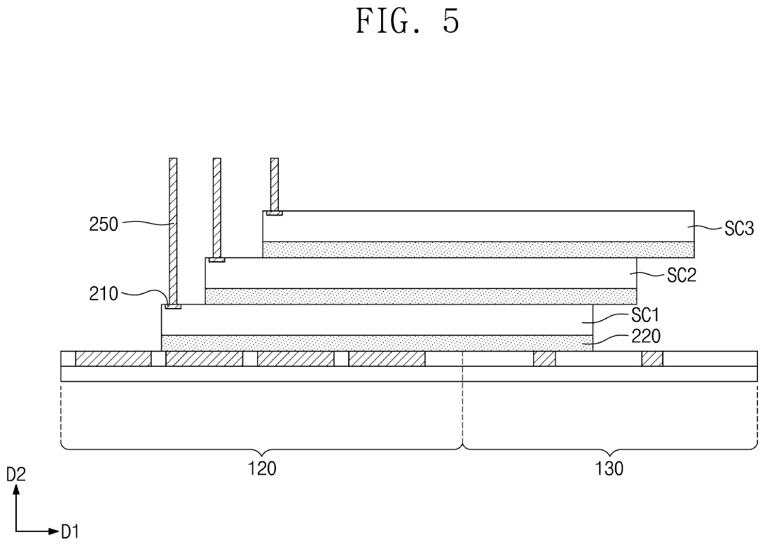

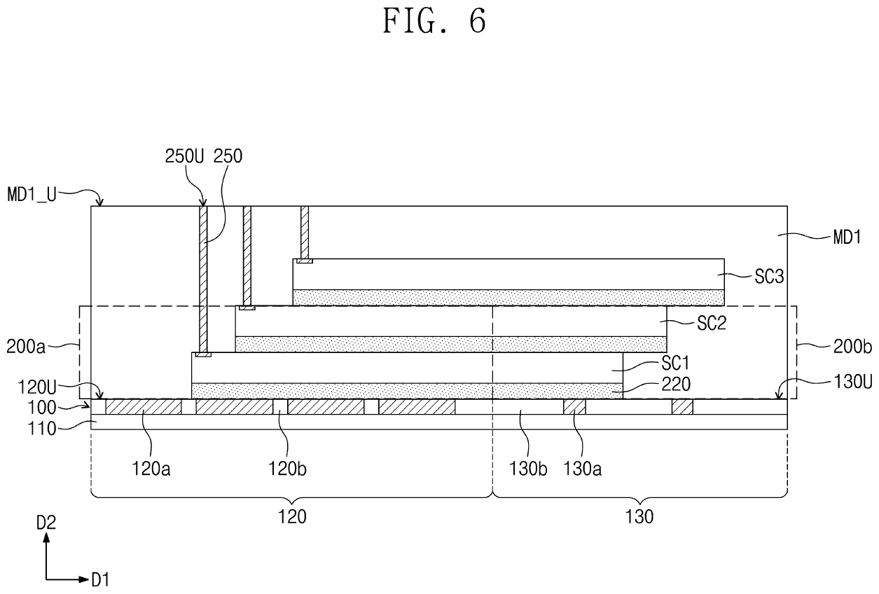

Referring to FIG. 5, the vertical connecting portions 250 may be formed on the semiconductor dies SC1, SC2, and SC3, respectively. The vertical connecting portions 250 may be formed by a wire bonding process. The wire bonding process may be performed using a wire bonding apparatus including a capillary.

In an embodiment, the formation of the vertical connecting portions 250 may include providing a wire for the vertical connecting portions 250 to the capillary, placing the wire for each of the vertical connecting portions 250 on/over a corresponding one of the contact pads 210, moving the capillary in a downward direction to attach an end of the wire for each of the vertical connecting portions 250 to a corresponding one of the contact pads 210, moving the capillary in an upward direction to vertically extend the wire for the vertical connecting portion 250 from the end, and cutting the wire to form each of the vertical connecting portions 250 such that the wire attached to the capillary to be separated from each of the vertical connecting portions attached to the contact pads 210.

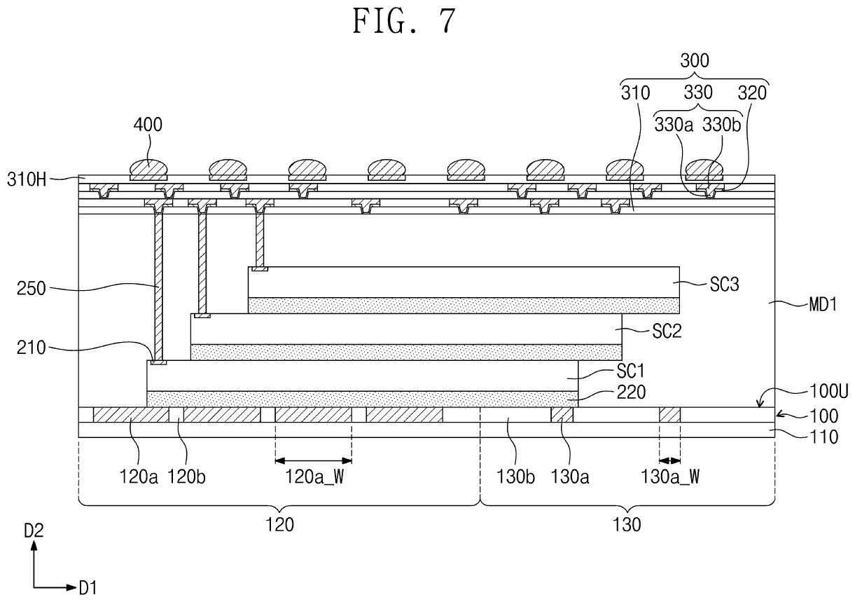

Referring to FIG. 6, the first mold layer MD1 may be formed on the first substrate 100. The first mold layer MD1 may cover the semiconductor dies SC1, SC2, and SC3 and the vertical connecting portions 250. In an embodiment, the formation of the first mold layer MD1 may include forming a liquid sealing agent on the first substrate 100, hardening the sealing agent, and planarizing the sealing agent to expose the top surface 250U of the vertical connecting portion 250.

The chip region 200a and the molding region 200b may be defined on the first substrate 100. A portion of the first mold layer MD1 and portions of the semiconductor dies SC1, SC2, and SC3, which are placed on the first region 120 of the first substrate 100, may be defined as the chip region 200a. Other portion of the first mold layer MD1 and other portions of the semiconductor dies SC1, SC2, and SC3, which are placed on the second region 130 of the first substrate 100, may be defined as the molding region 200b.

In the chip region 200a, a volume (or space) of the portions of the semiconductor dies SC1, SC2, and SC3 may be larger than that of the portion of the first mold layer MD1. In the molding region 200b, a volume (or space) of the other portion of the first mold layer MD1 may be larger than a volume (or space) of the other portions of the semiconductor dies SC1, SC2, and SC3. In this case, a thermal expansion coefficient (i.e., the rate of volume change caused by heat) may be smaller in the chip region 200a than in the molding region 200b. Due to the difference in the thermal expansion coefficient between the chip region 200a and the molding region 200b, a warpage failure may occur in the semiconductor package.

In an embodiment, the first and second regions 120 and 130 may be configured to reduce the variation in the thermal expansion coefficient of the semiconductor package. A content of a metallic material (e.g., copper) in the first region 120 may be higher than that in the second region 130. In this case, the first thermal expansion coefficient of the first region 120 may be higher than the second thermal expansion coefficient of the second region 130. Thus, it may be possible to reduce the difference in the thermal expansion coefficient between the chip region 200a and the molding region 200b. As a result, it may be possible to reduce a warpage failure in the semiconductor package. For example, it may be possible to prevent the semiconductor dies SC1, SC2, and SC3 of the semiconductor package from being damaged and to improve the reliability of the semiconductor package.

Referring to FIG. 7, the second substrate 300 may be formed on the first mold layer MD1. In an embodiment, the formation of the second substrate 300 may include forming the upper redistribution insulating layers 310 on the first mold layer MD1, forming upper redistribution contact holes to penetrate the upper redistribution insulating layers 310, forming the upper redistribution seed patterns 320 which partially fill the upper redistribution contact holes, respectively, and to cover top surfaces of the upper redistribution insulating layers 310, and performing an electroplating process using the upper redistribution seed patterns 320 to form the upper redistribution contacts 330a and the upper redistribution lines 330b. The upper redistribution contacts 330a may be formed to fill remaining portions of the upper redistribution contact holes, respectively, and each of the upper redistribution lines 330b may extend to a region on a top surface of a corresponding one of the upper redistribution insulating layers 310. The upper redistribution contacts 330a and the upper redistribution lines 330b may constitute the upper redistribution patterns 330. The first connection terminals 400 may be formed on a top surface of the uppermost one (e.g., the upper redistribution insulating layer 310H) of the upper redistribution insulating layers 310.

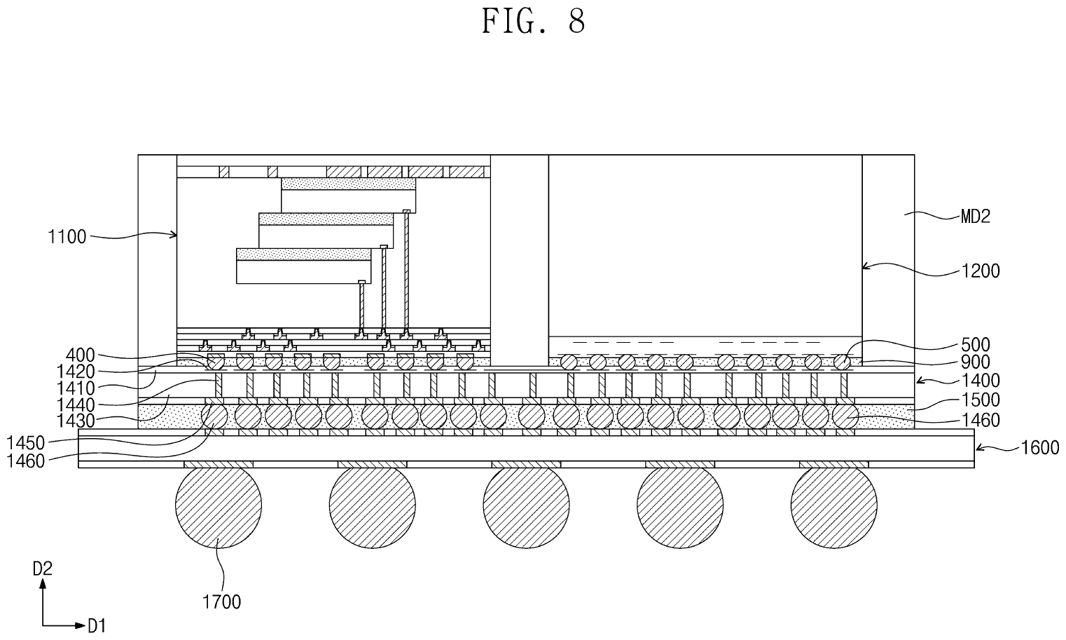

FIG. 8 is a sectional view illustrating a semiconductor package according to an embodiment of the inventive concept. For concise description, elements previously described with reference to FIG. 1 may be identified by the same reference numbers without repeating overlapping descriptions thereof.

The semiconductor package may further include a first semiconductor chip 1100, a second semiconductor chip 1200, a package substrate 1600, and an interposer 1400. The first semiconductor chip 1100 may be the semiconductor package described with reference to FIG. 1. In an embodiment, the package substrate 1600 may be one of a printed circuit board, a semiconductor chip, or a semiconductor package.

The interposer substrate 1400 may be provided on the package substrate 1600. The interposer substrate 1400 may include a base substrate 1430, a plurality of penetration electrodes 1440 penetrating the base substrate 1430 (e.g., in a vertical/thickness direction), and upper interconnection patterns 1420 formed on an upper surface of the base substrate 1430. The interposer substrate 1400 may further include lower interconnection patterns 1450 and outer connection members 1460, which are provided on a lower surface of the base substrate 1430. The upper interconnection patterns 1420 may be provided on an insulating layer 1410.

The first semiconductor chip 1100 may be electrically connected to the interposer substrate 1400 through the first connection terminal 400. The second semiconductor chip 1200 may be replaced with a semiconductor package in certain embodiments. The second semiconductor chip 1200 may be an application specific integrated circuit (ASIC) chip or a system-on-chip (SOC). The second semiconductor chip 1200 may be referred to as a host or an application processor (AP). The second semiconductor chip 1200 may be electrically connected to the interposer substrate 1400 through a second connection terminal 500.

A second mold layer MD2 may cover a top surface of the interposer substrate 1400, the first semiconductor chip 1100, and the second semiconductor chip 1200. For example, the second mold layer MD2 may cover side surfaces of the first semiconductor chip 1100 and the second semiconductor chip 1200 as shown in FIG. 8. In an embodiment, the second mold layer MD2 may include an insulating resin (e.g., an epoxy molding compound (EMC)). The second mold layer MD2 may further include fillers, which are dispersed in the insulating resin. In an embodiment, the fillers may include silicon oxide (SiO₂).

The interposer substrate 1400 may be bonded to the package substrate 1600 by the outer connection members 1460. Outer connection members 1700 may be bonded to a lower surface of the package substrate 1600. The outer connection members 1460 and 1700 may include or may be copper bumps, copper pillars, and/or solder balls.

According to an embodiment of the inventive concept, an under-fill layer 900 may be provided between the first semiconductor chip 1100 and the interposer substrate 1400 and between the second semiconductor chip 1200 and the interposer substrate 1400. An under-fill layer 1500 may be further provided between the interposer substrate 1400 and the package substrate 1600. The under-fill layers 900 and 1500 may be formed through a dispensing and curing process. The under-fill layers 900 and 1500 may include an epoxy resin and may protect the outer connection members 1460 and 1700.

According to an embodiment of the inventive concept, a semiconductor package may include semiconductor dies, which are stacked on a first substrate to have a stepwise structure. Since the semiconductor dies have the stepwise structure, a change rate in the volume of the semiconductor package caused by heat may vary depending on a position on a top surface of the first substrate. The first substrate may include a first region and a second region. The first region may have a thermal expansion coefficient higher than the second region. In this case, the nonuniformity issue of the volume change rate may be relieved by an application of features of the above described embodiments, and it may be possible to prevent the semiconductor dies from being damaged by a warpage failure of the semiconductor package. Accordingly, semiconductor packages with improved reliability may be provided according to embodiments of the present disclosure.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first substrate;
semiconductor dies stacked on the first substrate in a direction perpendicular to a top surface of the first substrate to have a stepwise structure;
a mold layer disposed on the first substrate to cover the semiconductor dies;
a second substrate disposed on the mold layer; and
vertical conductive lines electrically connecting the semiconductor dies to the second substrate,
wherein the first substrate comprises a first region and a second region,
the first region has a first thermal expansion coefficient,
the second region has a second thermal expansion coefficient, and
the first thermal expansion coefficient is different from the second thermal expansion coefficient.

2. The semiconductor package of claim 1, wherein the first thermal expansion coefficient is greater than the second thermal expansion coefficient.

3. The semiconductor package of claim 1, wherein the first region comprises first metal patterns and a first insulating pattern covering the first metal patterns, and
the second region comprises second metal patterns and a second insulating pattern covering the second metal patterns.

4. The semiconductor package of claim 3, wherein a width of each of the first metal patterns in a first direction is different from a width of each of the second metal patterns in the first direction, and
the first direction is a direction parallel to the top surface of the first substrate.

5. The semiconductor package of claim 3, wherein a width of each of the first metal patterns in a first direction is larger than a width of each of the second metal patterns in the first direction, and
the first direction is parallel to the top surface of the first substrate.

6. The semiconductor package of claim 3, wherein a ratio of a width of each of the first metal patterns in a first direction to a width of each of the second metal patterns in the first direction ranges from 1:0.1 to 1:0.7, and
the first direction is parallel to the top surface of the first substrate.

7. The semiconductor package of claim 3, wherein the number of the first metal patterns is different from the number of the second metal patterns.

8. The semiconductor package of claim 3, wherein the number of the first metal patterns is greater than the number of the second metal patterns.

9. The semiconductor package of claim 3, wherein a ratio of the number of the first metal patterns to the number of the second metal patterns ranges from 1:0.1 to 1:0.7.

10. The semiconductor package of claim 3, wherein the first metal patterns comprise the same metal as the second metal patterns.

11. The semiconductor package of claim 1, wherein a ratio of a width of the first region in a first direction to a width of the second region in the first direction ranges from 1:1 to 7:3.

12. A semiconductor package, comprising:
a first substrate;
semiconductor dies stacked on the first substrate in a direction perpendicular to a top surface of the first substrate to have a stepwise structure;
a mold layer disposed on the first substrate to cover the semiconductor dies;
a second substrate disposed on the mold layer; and
vertical conductive lines electrically connecting the semiconductor dies to the second substrate,
wherein the first substrate comprises a first region and a second region,
the first region comprises first metal patterns and a first insulating pattern covering the first metal patterns,
the second region comprises second metal patterns and a second insulating pattern covering the second metal patterns,
a width of each of the first metal patterns in a first direction is larger than a width of each of the second metal patterns in the first direction, and
the first direction is parallel to the top surface of the first substrate.

13. The semiconductor package of claim 12, wherein the first region has a first thermal expansion coefficient,
the second region has a second thermal expansion coefficient, and
the first thermal expansion coefficient is different from the second thermal expansion coefficient.

14. The semiconductor package of claim 13, wherein the first thermal expansion coefficient is greater than the second thermal expansion coefficient.

15. The semiconductor package of claim 12, wherein the first metal patterns and the second metal patterns comprise the same metal, and
the metal is copper.

16. The semiconductor package of claim 12, wherein the second substrate comprises an upper redistribution pattern and an upper redistribution insulating layer covering the upper redistribution pattern, and
the vertical conductive lines are electrically connected to the upper redistribution pattern.

17. A semiconductor package, comprising:
a first substrate;
semiconductor dies stacked on the first substrate in a direction perpendicular to a top surface of the first substrate to have a stepwise structure;
a mold layer disposed on the first substrate to cover the semiconductor dies;
a second substrate disposed on the mold layer, the second substrate comprising upper redistribution patterns and upper redistribution insulating layers enclosing the upper redistribution patterns; and
vertical conductive lines electrically connecting the semiconductor dies to the upper redistribution patterns of the second substrate,
wherein the first substrate comprises a first region and a second region,
the first region comprises first metal patterns and a first insulating pattern covering the first metal patterns,
the second region comprises second metal patterns and a second insulating pattern covering the second metal patterns, and
the number of the first metal patterns is greater than the number of the second metal patterns.

18. The semiconductor package of claim 17, wherein a first thermal expansion coefficient of the first region is greater than a second thermal expansion coefficient of the second region.

19. The semiconductor package of claim 17, wherein a ratio of a width of the first region in a first direction to a width of the second region in the first direction ranges from 1:1 to 7:3, and
the first direction is parallel to the top surface of the first substrate.

20. The semiconductor package of claim 17, wherein a top surface of the mold layer is located on the same plane as a top surface of each of the vertical conductive lines.
